(19) United States
(12) Patent Application Publication
(10) Pub. No.: US 2026/0291442 A1
(43) Pub. Date: Sep. 24, 2026

(54) DOHERTY AMPLIFIER CIRCUIT

(71) Applicant: Murata Manufacturing Co., Ltd., Nagaokakyo-shi (JP)

(72) Inventor: Shohei IMAI, Nagaokakyo-shi (JP)

(21) Appl. No.: 19/554,754

(22) Filed: Mar. 3, 2026

(30) Foreign Application Priority Data
Mar. 24, 2025 (JP) 2025-048699

(51) Int. Cl. H03F 1/02; H03F 3/21

(52) U.S. Cl. CPC H03F 1/0288; H03F 3/211; H03F 2200/451

(57) ABSTRACT

A carrier amplifier unit includes a carrier amplifier to which a radio frequency signal split from an input signal is input and that amplifies and outputs the input radio frequency signal, and a transformer that transforms an output impedance of the carrier amplifier. A radio frequency signal split from the input signal is inputted to a peaking amplifier unit, and the peaking amplifier unit amplifies and outputs the input radio frequency signal. In a case where a power level of the input signal at a start of an amplification operation is used as an operation start level, the peaking amplifier unit has a higher operation start level than the carrier amplifier unit. The carrier amplifier unit and the peaking amplifier unit are connected on an output side in a first connection configuration, which is either a series connection or a parallel connection.

### CROSS REFERENCE TO RELATED APPLICATION

This application claims priority from Japanese Patent Application No. 2025-048699, filed on Mar. 24, 2025. The content of these applications are incorporated herein by reference in its entirety.

### BACKGROUND OF THE DISCLOSURE

### 1. Field of the Disclosure

The present disclosure relates to a Doherty amplifier circuit.

### 2. Description of the Related Art

A Doherty amplifier circuit is used as a highly efficient radio-frequency power amplifier circuit. A Doherty amplifier circuit generally includes a carrier amplifier that operates regardless of the power level of an input signal and a peaking amplifier that does not operate when the power level of the input signal is less than or equal to a predetermined operation start level and operates in the range where the power level of the input signal exceeds the operation start level. A multi-way Doherty amplifier circuit including multiple peaking amplifiers having different operation start levels is known (Japanese Unexamined Patent Application Publication No. 2021-192476). In the multi-way Doherty amplifier circuit described in Japanese Unexamined Patent Application Publication No. 2021-192476, the carrier amplifier and multiple peaking amplifiers are connected in series or in parallel on the output side.

### BRIEF SUMMARY OF THE DISCLOSURE

When the carrier amplifier and multiple peaking amplifiers are connected in series on the output side, the radio frequency signal outputted from the carrier amplifier flows equally into the output side of the multiple peaking amplifiers. As a result, the power of the radio frequency signal is consumed by the multiple peaking amplifiers, resulting in increased losses. When the carrier amplifier and multiple peaking amplifiers are connected in parallel on the output side, the voltage of the radio frequency signal outputted from the carrier amplifier is equally applied to the output side of the multiple peaking amplifiers. As a result, the power of the radio frequency signal is consumed by the multiple peaking amplifiers, resulting in increased losses.

The present disclosure aims to provide a Doherty amplifier circuit including a carrier amplifier and multiple peaking amplifiers to reduce losses.

According to an aspect of the present disclosure, there is provided a Doherty amplifier circuit including: a carrier amplifier unit including a carrier amplifier to which a radio frequency signal split from an input signal is input and that amplifies and outputs the input radio frequency signal, and a transformer that transforms an output impedance of the carrier amplifier, and a peaking amplifier unit to which a radio frequency signal split from the input signal is input and that amplifies and outputs the input radio frequency signal,
in which in a case where a power level of the input signal at a start of an amplification operation is used as an operation start level, the peaking amplifier unit has a higher operation start level than the carrier amplifier unit, the carrier amplifier unit and the peaking amplifier unit are connected on an output side in a first connection configuration, which is either a series connection or a parallel connection, the peaking amplifier unit includes a first amplification unit and a second amplification unit connected on the output side in a second connection configuration, which is either a series connection or a parallel connection and different from the first connection configuration, each of the first amplification unit and the second amplification unit amplifies and outputs the radio frequency signals split from the input signal, and the first amplification unit and the second amplification unit have different output impedances, and the first amplification unit has a lower operation start level than the second amplification unit.

Since the first amplification unit and the second amplification unit have different output impedances, the power of the radio frequency signal outputted from the carrier amplifier is mainly consumed by either the first amplification unit or the second amplification unit, and a small amount of power is consumed by the other. The overall loss of the Doherty amplifier circuit can thus be suppressed.

### BRIEF DESCRIPTION OF THE SEVERAL VIEWS OF THE DRAWINGS

FIG. 1 is a block diagram of a Doherty amplifier circuit according to a first embodiment;

FIG. 2A is a graph illustrating an example of the relationship between the input power and the output power of the Doherty amplifier circuit according to the first embodiment, and FIG. 2B is a graph illustrating an example of the relationship between the input power and the efficiency of the Doherty amplifier circuit according to the first embodiment;

FIG. 3 is a block diagram of a Doherty amplifier circuit according to a comparative example;

FIG. 4 is a block diagram of a Doherty amplifier circuit according to a second embodiment;

FIG. 5 is a block diagram of a Doherty amplifier circuit according to a comparative example;

FIG. 6 is a block diagram of a Doherty amplifier circuit according to a third embodiment;

FIG. 7 is a block diagram of a Doherty amplifier circuit according to a fourth embodiment;

FIG. 8 is a block diagram of a first amplification unit 31A (FIGS. 1, 4, 6, and 7) included in a Doherty amplifier circuit according to a fifth embodiment;

FIG. 9 is an equivalent circuit diagram of a first transformer 41 that performs impedance transformation such that the first amplification unit 31A (FIG. 8) or the like can be considered a current source;

FIG. 10 is an equivalent circuit diagram of a second transformer 45 that performs impedance transformation such that the first amplification unit 31A (FIG. 8) can be considered a voltage source;

FIG. 11 is a block diagram of a Doherty amplifier circuit according to a comparative example;

FIG. 12A is a graph illustrating calculation results of the frequency dependence of the loss of the Doherty amplifier circuit according to the comparative example (FIG. 11), and FIG. 12B is a graph illustrating calculation results of the frequency dependence of the loss of the Doherty amplifier circuit according to the third embodiment (FIG. 6);

FIG. 13 is a block diagram of a Doherty amplifier circuit according to a sixth embodiment; and

FIG. 14 is a block diagram of a Doherty amplifier circuit according to a seventh embodiment.

### DETAILED DESCRIPTION OF THE DISCLOSURE

### First Embodiment

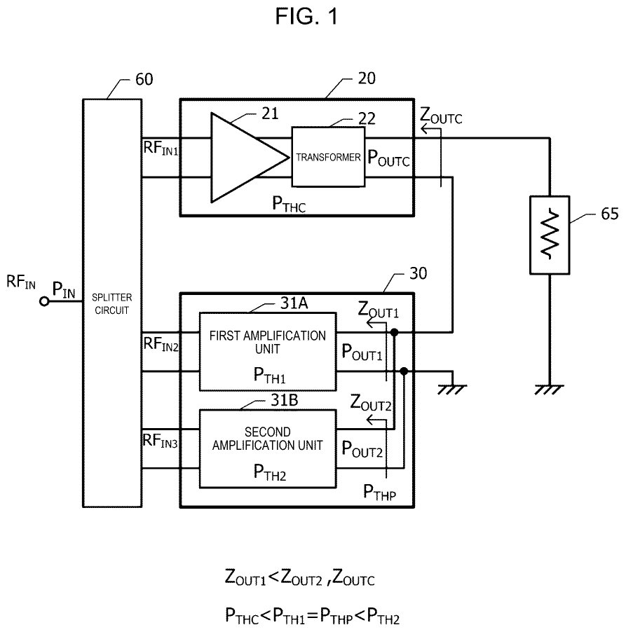

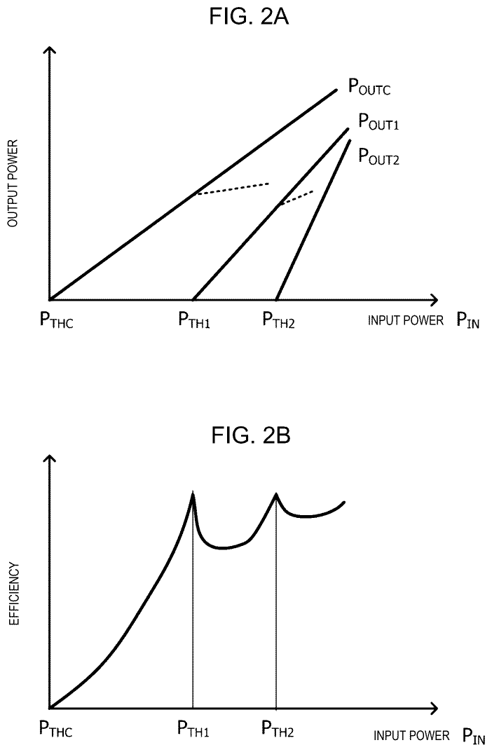

A Doherty amplifier circuit according to a first embodiment will be described with reference to FIGS. 1, 2A, and 2B.

FIG. 1 is a block diagram of the Doherty amplifier circuit according to the first embodiment. The Doherty amplifier circuit according to the first embodiment includes a carrier amplifier unit 20 and a peaking amplifier unit 30. The carrier amplifier unit 20 and the peaking amplifier unit 30 are connected in series on the output side. The carrier amplifier unit 20 includes a carrier amplifier 21 and a transformer 22. The peaking amplifier unit 30 includes a first amplification unit 31A and a second amplification unit 31B.

A splitter circuit 60 splits an input signal RF_{IN} to generate multiple radio frequency signals RF_{IN1}, RF_{IN2}, and RF_{IN3}. The power level of the input signal RF_{IN} is used as input power_{IN}. For example, the input signal RF_{IN} is a single-ended signal, and the radio frequency signals RF_{IN1}, RF_{IN2}, RF_{IN3} are differential signals. The carrier amplifier 21 is a differential amplifier. Each of the first amplification unit 31A and the second amplification unit 31B includes a differential amplifier. The phases of the radio frequency signals RF_{IN2} and RF_{IN3} lead the phase of the radio frequency signal RF_{IN1} by 90° and 180°, respectively.

The radio frequency signal RF_{IN1} is inputted to the carrier amplifier 21 of the carrier amplifier unit 20. The carrier amplifier 21 amplifies and outputs the input radio frequency signal RF_{IN1}. The transformer 22 transforms the output impedance of the carrier amplifier 21 and phase-shifts the radio frequency signal outputted from the carrier amplifier 21. The impedance (output impedance) seen looking into the carrier amplifier unit 20 from the output node of the carrier amplifier unit 20 is denoted as Z_{OUTC}. The radio frequency signal outputted from the carrier amplifier unit 20 is a differential signal, and its power level is used as output power_{OUTC}.

The radio frequency signals RF_{IN2} and RF_{IN3} are inputted to the peaking amplifier unit 30. The peaking amplifier unit 30 amplifies each of the input radio frequency signals RF_{IN2} and RF_{IN3} and then combines and outputs the amplified signals. Specifically, the peaking amplifier unit 30 includes the first amplification unit 31A and the second amplification unit 31B. The radio frequency signal RF_{IN2} is inputted to the first amplification unit 31A, and the radio frequency signal RF_{IN3} is inputted to the second amplification unit 31B. The first amplification unit 31A and the second amplification unit 31B amplify the radio frequency signals RF_{IN2} and RF_{IN3}, which are differential signals, respectively and transform them into single-ended signals to output them.

The first amplification unit 31A and the second amplification unit 31B are connected in parallel on the output side. That is, the series-parallel connection configuration of the first amplification unit 31A and the second amplification unit 31B on the output side is different from the output-side connection configuration of the carrier amplifier unit 20 and the peaking amplifier unit 30.

For example, one output node of each of the first amplification unit 31A and the second amplification unit 31B is connected to ground, and the other output nodes (ungrounded output nodes) of the first amplification unit 31A and the second amplification unit 31B are connected to each other. The ungrounded output nodes and the output nodes connected to ground constitute a pair of output nodes of the peaking amplifier unit 30. The power levels of the radio frequency signals outputted from the first amplification unit 31A and the second amplification unit 31B are used as output power_{OUT1} and P_{OUT2}, respectively. The output impedances of the first amplification unit 31A and the second amplification unit 31B are denoted as Z_{OUT1} and Z_{OUT2}, respectively.

The output impedances Z_{OUTC}, Z_{OUT1}, and Z_{OUT2} can be calculated, for example, based on a reflection coefficient and the characteristic impedance of the output line when a radio frequency signal is inputted to the output node in a state where the bias is set for Class C and the input node is shorted.

The carrier amplifier unit 20 and the peaking amplifier unit 30 are connected in series on the output side and are also connected to a load 65. For example, the ungrounded output node of the peaking amplifier unit 30 is connected to an inverted output node of the carrier amplifier unit 20. The load 65 is connected between a non-inverted output node of the carrier amplifier unit 20 and ground.

The output impedance Z_{OUT1} of the first amplification unit 31A is lower than the output impedance Z_{OUTC} of the carrier amplifier unit 20. The output impedance Z_{OUT2} of the second amplification unit 31B is higher than the output impedance Z_{OUT1} of the first amplification unit 31A. In accordance with the magnitude relationship between the output impedances, the carrier amplifier unit 20, the first amplification unit 31A, and the second amplification unit 31B can be considered a current source or a voltage source. For example, the carrier amplifier unit 20 and the second amplification unit 31B having relatively high output impedances, which are Z_{OUTC} and Z_{OUT2}, can be considered a current source, and the first amplification unit 31A having a relatively low output impedance, which is Z_{OUT1}, can be considered a voltage source.

An input power P_{IN} when the carrier amplifier unit 20 starts its amplification operation is used as an operation start level P_{THC}. Operation start levels of the first amplification unit 31A and the second amplification unit 31B are denoted as P_{THP1} and P_{THP2}, respectively. For example, the carrier amplifier 21 is biased in Class AB, and the operation start level P_{THC} of the carrier amplifier unit 20 is 0 dBm.

The operation start level P_{TH1} of the first amplification unit 31A is higher than the operation start level P_{THC} of the carrier amplifier unit 20. The operation start level P_{TH2} of the second amplification unit 31B is higher than the operation start level P_{TH1} of the first amplification unit 31A. For example, the operation start level P_{TH1} is set near the average power level of the input signal RF_{IN} (the back-off region). For example, the first amplification unit 31A and the second amplification unit 31B are biased in Class C, and the second amplification unit 31B is more heavily biased than the first amplification unit 31A. In this configuration, an operation start level P_{THP} of the peaking amplifier unit 30 is equal to the operation start level P_{TH1} of the first amplification unit 31A. That is, the operation start level P_{THP} of the peaking amplifier unit 30 is higher than the operation start level P_{THC} of the carrier amplifier unit 20.

Next, the operation of the Doherty amplifier circuit according to the first embodiment will be described with reference to FIG. 2A. FIG. 2A is a graph illustrating an example of the relationship between the input power P_{IN} and the output power of the Doherty amplifier circuit according to the first embodiment. The horizontal axis in FIG. 2A represents the input power P_{IN}, and the vertical axis represents output powers P_{OUTC}, P_{OUT1}, and P_{OUT2}. The carrier amplifier unit 20 operates in the range where the input power P_{IN} is greater than or equal to the operation start level P_{THC}, and the output power P_{OUTC} increases as the input power P_{IN} increases. When the input power P_{IN} increases further, the output power P_{OUTC} of the carrier amplifier unit 20 saturates as represented by the broken line.

The first amplification unit 31A starts operating at the input power P_{IN} (i.e., the operation start level P_{TH1} of the first amplification unit 31A) obtained when the output power P_{OUTC} of the carrier amplifier unit 20 saturates, so that the output power_{OUT1} of the first amplification unit 31A rises. When the input power_{IN} increases further, the output power_{OUT1} of the first amplification unit 31A saturates as represented by the broken line. The second amplification unit 31B starts operating at the input power_{IN} (i.e., the operation start level P_{TH2} of the second amplification unit 31B) obtained when the output power_{OUT1} of the first amplification unit 31A saturates, so that the output power_{OUT2} of the second amplification unit 31B rises.

Note that when the first amplification unit 31A starts operating in the range where the input power_{IN} is greater than or equal to the operation start level P_{TH1}, the output power_{OUTC} of the carrier amplifier unit 20 becomes higher than the saturation level as represented by the solid line. Similarly, when the second amplification unit 31B starts operating in the range where the input power_{IN} is greater than or equal to the operation start level P_{TH2}, the output power_{OUT1} of the first amplification unit 31A becomes higher than the saturation level as represented by the solid line.

FIG. 2B is a graph illustrating an example of the relationship between the input power P_{IN} and the efficiency of the Doherty amplifier circuit according to the first embodiment. The horizontal axis represents the input power_{IN}, and the vertical axis represents efficiency. In the range less than or equal to the operation start level P_{TH1}, only the carrier amplifier unit 20 operates and the peaking amplifier unit 30 does not operate. Since the carrier amplifier unit 20 saturates near the operation start level P_{TH1} (the back-off region), high efficiency can be achieved in the back-off region. Similarly, the second amplification unit 31B does not operate in the range greater than or equal to the operation start level P_{TH1} and less than or equal to P_{TH2}, and the carrier amplifier unit 20 and the first amplification unit 31A saturate near the operation start level P_{TH1}, so that high efficiency can be achieved.

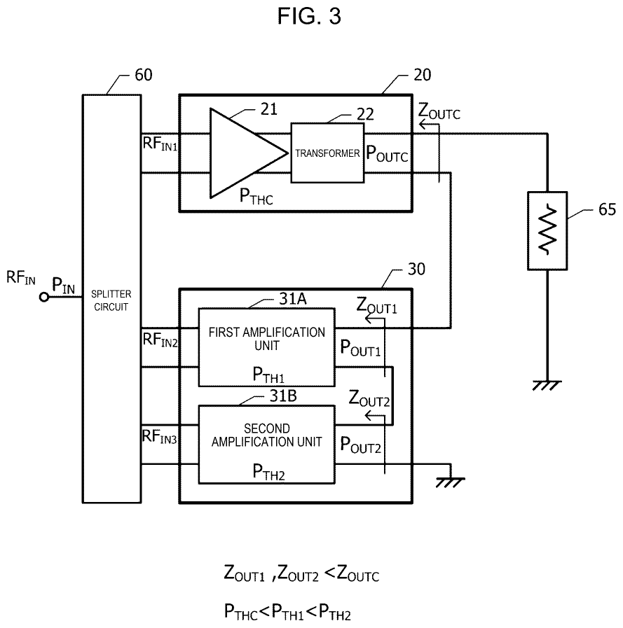

Next, an effect of the first embodiment will be described, compared with a comparative example illustrated in FIG. 3.

FIG. 3 is a block diagram of a Doherty amplifier circuit according to the comparative example. In the comparative example illustrated in FIG. 3, the carrier amplifier unit 20 and the peaking amplifier unit 30 are connected in series on the output side, and the first amplification unit 31A and the second amplification unit 31B are also connected in series on the output side. To supply the output current from the carrier amplifier unit 20, which can be considered a current source, to the load 65, the output impedances Z_{OUT1} and Z_{OUT2} of both the first amplification unit 31A and the second amplification unit 31B need to be made lower than the output impedance Z_{OUTC} of the carrier amplifier unit 20. In this case, the output current from the carrier amplifier unit 20 flows through both the first amplification unit 31A and the second amplification unit 31B. This causes losses in both the first amplification unit 31A and the second amplification unit 31B.

In the first embodiment (FIG. 1), the output current from the carrier amplifier unit 20, which can be considered a current source, flows mainly through the first amplification unit 31A having the lower output impedance, which is Z_{OUT1}, out of the first amplification unit 31A and the second amplification unit 31B of the peaking amplifier unit 30, and a small amount of current flows through the second amplification unit 31B having the higher output impedance, which is Z_{OUT2}. Thus, the overall loss of the Doherty amplifier circuit can be suppressed.

Furthermore, in the first embodiment, the operation start level P_{TH1} of the first amplification unit 31A having the output impedance Z_{OUT1}, which is relatively low, is lower than the operation start level P_{TH2} of the second amplification unit 31B having the output impedance Z_{OUT2}, which is relatively high. If the second amplification unit 31B having the higher output impedance, which is Z_{OUT2}, operates first, the power of the radio frequency signal outputted from the second amplification unit 31B is consumed by the first amplification unit 31A having the lower output impedance, which is Z_{OUT1}, than the load 65 and the carrier amplifier unit 20, resulting in increased losses. In the first embodiment, the first amplification unit 31A having the output impedance Z_{OUT1}, which is relatively low, starts operating before the second amplification unit 31B having the output impedance Z_{OUT2}, which is relatively high, does, so that the increase in loss is suppressed.

### Second Embodiment

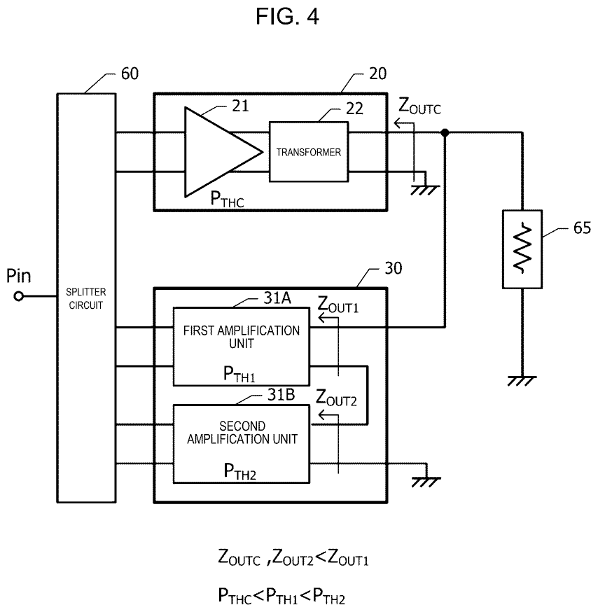

Next, a Doherty amplifier circuit according to a second embodiment will be described with reference to FIG. 4. In the following, description of the configuration common to that of the Doherty amplifier circuit according to the first embodiment described with reference to FIGS. 1, 2A, and 2B will be omitted.

FIG. 4 is a block diagram of the Doherty amplifier circuit according to the second embodiment. In the first embodiment (FIG. 1), the carrier amplifier unit 20 and the peaking amplifier unit 30 are connected in series on the output side; however, in the second embodiment, the carrier amplifier unit 20 and the peaking amplifier unit 30 are connected in parallel on the output side.

The carrier amplifier unit 20 outputs a single-ended signal. One output node of the carrier amplifier unit 20 is connected to ground. The load 65 is connected between an ungrounded output node of the carrier amplifier unit 20 and ground.

One output node of the peaking amplifier unit 30 is connected to ground, and the other output node, which is ungrounded, is connected to the ungrounded output node of the carrier amplifier unit 20. The transformer 22 of the carrier amplifier unit 20 is configured such that the output impedance Z_{OUTC} of the carrier amplifier unit 20 is lower than the output impedance of the carrier amplifier 21. Furthermore, the transformer 22 is configured such that the output impedance Z_{OUTC} of the carrier amplifier unit 20 is lower than the output impedance of the peaking amplifier unit 30. In this case, the carrier amplifier unit 20 can be considered a voltage source.

The first amplification unit 31A and the second amplification unit 31B of the peaking amplifier unit 30 are connected in series on the output side. That is, the series-parallel connection configuration of the first amplification unit 31A and the second amplification unit 31B on the output side is different from the output-side connection configuration of the carrier amplifier unit 20 and the peaking amplifier unit 30.

The first amplification unit 31A outputs a differential signal, and the second amplification unit 31B outputs a single-ended signal. One output node of the second amplification unit 31B constitutes a grounded output node of the peaking amplifier unit 30.

The ungrounded output node of the second amplification unit 31B is connected to the inverted output node of the first amplification unit 31A, and the non-inverted output node of the first amplification unit 31A constitutes the ungrounded output node of the peaking amplifier unit 30. The output impedance Z_{OUT1} of the first amplification unit 31A is higher than the output impedance Z_{OUTC} of the carrier amplifier unit 20. The output impedance Z_{OUT2} of the second amplification unit 31B is lower than the output impedance Z_{OUT1} of the first amplification unit 31A.

The magnitude relationship between the operation start levels P_{THC}, P_{TH1}, and P_{TH2} of the carrier amplifier unit 20, the first amplification unit 31A, and the second amplification unit 31B, respectively, is the same as the magnitude relationship between these in the Doherty amplifier circuit according to the first embodiment. As with the Doherty amplifier circuit according to the first embodiment, high efficiency can thus be achieved.

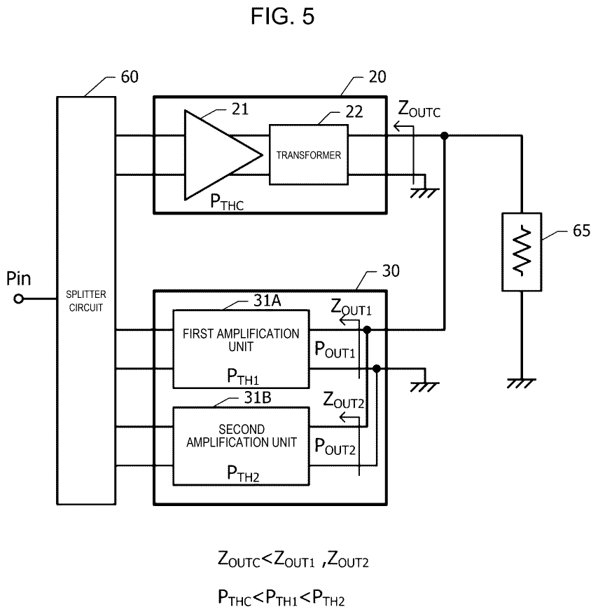

Next, an effect of the second embodiment will be described, compared with a comparative example illustrated in FIG. 5.

FIG. 5 is a block diagram of a Doherty amplifier circuit according to the comparative example. In the comparative example illustrated in FIG. 5, the carrier amplifier unit 20 and the peaking amplifier unit 30 are connected in parallel on the output side, and the first amplification unit 31A and the second amplification unit 31B are also connected in parallel on the output side. The output impedance Z_{OUT1} of the first amplification unit 31A and the output impedance Z_{OUT2} of the second amplification unit 31B are higher than the output impedance Z_{OUTC} of the carrier amplifier unit 20. The output voltage from the carrier amplifier unit 20 is applied to both the first amplification unit 31A and the second amplification unit 31B. Thus, similar losses occur in both the first amplification unit 31A and the second amplification unit 31B.

In contrast, in the second embodiment (FIG. 4), the output voltage from the carrier amplifier unit 20 is mainly applied to the first amplification unit 31A having the higher output impedance, which is Z_{OUT1}, and a low voltage is applied to the second amplification unit 31B having the lower output impedance, which is Z_{OUT2}. Thus, the loss occurring in the second amplification unit 31B is reduced. As a result, the overall loss of the Doherty amplifier circuit can be suppressed.

Furthermore, in the second embodiment, the operation start level P_{TH1} of the first amplification unit 31A having the output impedance Z_{OUT1}, which is relatively high, is lower than the operation start level P_{TH2} of the second amplification unit 31B having the output impedance Z_{OUT2}, which is relatively low. If the second amplification unit 31B having the output impedance Z_{OUT2}, which is relatively low, operates first, the output current from the second amplification unit 31B is supplied to the load 65 through the first amplification unit 31A having the output impedance Z_{OUT1}, which is relatively high. This increases loss in the first amplification unit 31A.

In the second embodiment, when the first amplification unit 31A operates first, the current outputted from the first amplification unit 31A flows through the second amplification unit 31B having the output impedance Z_{OUT2}, which is relatively low. Thus, the loss in the second amplification unit 31B is small. As a result, the overall loss of the Doherty amplifier circuit can be suppressed.

### Third Embodiment

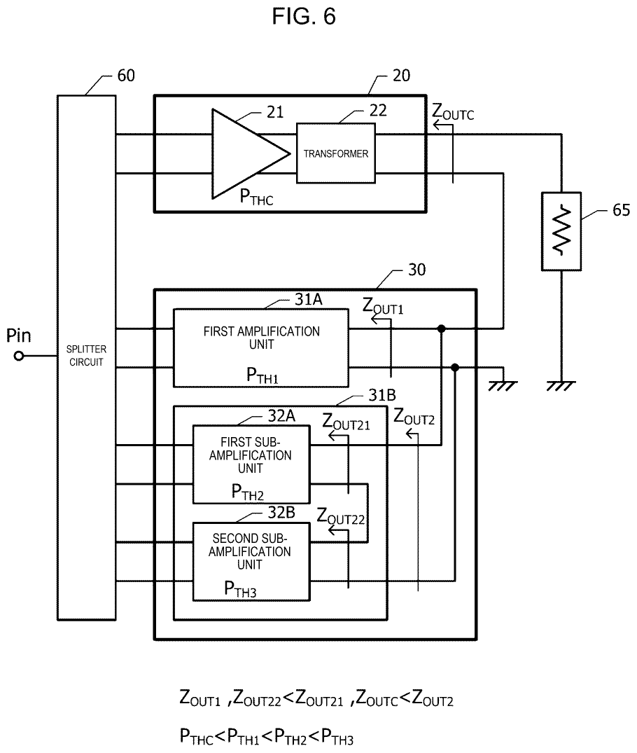

Next, a Doherty amplifier circuit according to a third embodiment will be described with reference to FIG. 6. In the following, description of the configuration common to that of the Doherty amplifier circuit according to the first embodiment described with reference to FIGS. 1, 2A, and 2B will be omitted.

FIG. 6 is a block diagram of the Doherty amplifier circuit according to the third embodiment. In the third embodiment, the second amplification unit 31B of the Doherty amplifier circuit according to the first embodiment (FIG. 1) includes a first sub-amplification unit 32A and a second sub-amplification unit 32B. The first sub-amplification unit 32A and the second sub-amplification unit 32B are connected in series on the output side. That is, the series-parallel connection configuration of the first sub-amplification unit 32A and the second sub-amplification unit 32B on the output side is different from the output-side connection configuration of the first amplification unit 31A and the second amplification unit 31B.

The first sub-amplification unit 32A outputs a differential signal, and the second sub-amplification unit 32B outputs a single-ended signal. One output node of the second sub-amplification unit 32B is connected to ground, and the other output node, which is ungrounded, is connected to the inverted output node of the first sub-amplification unit 32A. The non-inverted output node of the first sub-amplification unit 32A is connected to the ungrounded output node of the first amplification unit 31A.

The output impedance Z_{OUT21} of the first sub-amplification unit 32A is higher than the output impedance Z_{OUT1} of the first amplification unit 31A. The output impedance Z_{OUT22} of the second sub-amplification unit 32B is lower than the output impedance Z_{OUT21} of the first sub-amplification unit 32A. Thus, as with the case of the first embodiment, the output impedance Z_{OUT2} of the second amplification unit 31B becomes higher than the output impedance Z_{OUT1} of the first amplification unit 31A.

The operation start level P_{TH2} of the first sub-amplification unit 32A is lower than the operation start level P_{TH3} of the second sub-amplification unit 32B. Thus, the operation start level of the second amplification unit 31B is equal to the operation start level P_{TH2} of the first sub-amplification unit 32A.

Next, an effect of the third embodiment will be described.

Since the output impedance Z_{OUT2} of the second amplification unit 31B is higher than the output impedance Z_{OUT1} of the first amplification unit 31A, the overall loss of the Doherty amplifier circuit can be suppressed, as with the case of the first embodiment (FIG. 1).

Furthermore, the output-side connection configuration, the magnitude relationship between the output impedances, and the magnitude relationship between the operation start levels of the first amplification unit 31A, the first sub-amplification unit 32A, and the second sub-amplification unit 32B according to the third embodiment are identical to those of the carrier amplifier unit 20, the first amplification unit 31A, and the second amplification unit 31B according to the second embodiment (FIG. 4). Thus, the overall loss of the peaking amplifier unit 30 can be suppressed.

### Fourth Embodiment

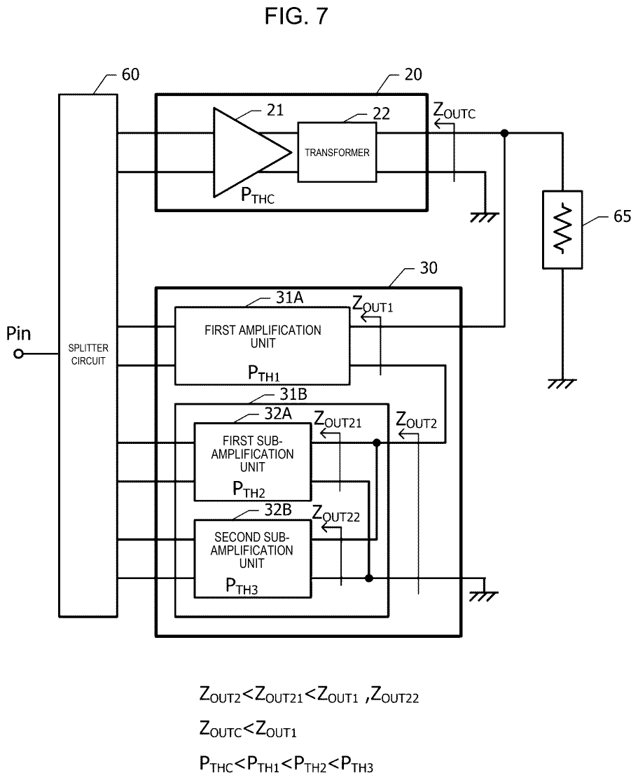

Next, a Doherty amplifier circuit according to a fourth embodiment will be described with reference to FIG. 7. In the following, description of the configuration common to that of the Doherty amplifier circuit according to the second embodiment described with reference to FIG. 4 will be omitted.

FIG. 7 is a block diagram of the Doherty amplifier circuit according to the fourth embodiment. In the fourth embodiment, the second amplification unit 31B of the Doherty amplifier circuit according to the second embodiment (FIG. 4) includes the first sub-amplification unit 32A and the second sub-amplification unit 32B. The first sub-amplification unit 32A and the second sub-amplification unit 32B are connected in parallel on the output side. That is, the series-parallel connection configuration of the first sub-amplification unit 32A and the second sub-amplification unit 32B on the output side is different from the output-side connection configuration of the first amplification unit 31A and the second amplification unit 31B.

The first sub-amplification unit 32A and the second sub-amplification unit 32B output a single-ended signal. One output node of the first sub-amplification unit 32A and one output node of the second sub-amplification unit 32B are connected to ground. The ungrounded output node of the first sub-amplification unit 32A and the ungrounded output node of the second sub-amplification unit 32B are connected to the inverted output node of the first amplification unit 31A.

The output impedance Z_{OUT21} of the first sub-amplification unit 32A is lower than the output impedance Z_{OUT1} of the first amplification unit 31A. The output impedance Z_{OUT22} of the second sub-amplification unit 32B is higher than the output impedance Z_{OUT21} of the first sub-amplification unit 32A. Thus, as with the case of the second embodiment, the output impedance Z_{OUT2} of the second amplification unit 31B becomes lower than the output impedance Z_{OUT1} of the first amplification unit 31A. The output impedance Z_{OUT1} of the first amplification unit 31A is higher than the output impedance Z_{OUTC} of the carrier amplifier unit 20, as with the case of the second embodiment (FIG. 4).

The operation start level P_{TH2} of the first sub-amplification unit 32A is lower than the operation start level P_{TH3} of the second sub-amplification unit 32B. Thus, the operation start level of the second amplification unit 31B is equal to the operation start level P_{TH2} of the first sub-amplification unit 32A.

Next, an effect of the fourth embodiment will be described.

Since the output impedance Z_{OUT2} of the second amplification unit 31B is lower than the output impedance Z_{OUT1} of the first amplification unit 31A, the overall loss of the Doherty amplifier circuit can be suppressed, as with the case of the second embodiment (FIG. 4).

Furthermore, the output-side connection configuration, the magnitude relationship between the output impedances, and the magnitude relationship between the operation start levels of the first amplification unit 31A, the first sub-amplification unit 32A, and the second sub-amplification unit 32B according to the fourth embodiment are identical to those of the carrier amplifier unit 20, the first amplification unit 31A, and the second amplification unit 31B according to the first embodiment (FIG. 1). Thus, the output current from the first amplification unit 31A mainly flows through the first sub-amplification unit 32A having the low output impedance Z_{OUT21}, and a small amount of current flows through the second sub-amplification unit 32B. Thus, the overall loss of the peaking amplifier unit 30 can be suppressed.

### Fifth Embodiment

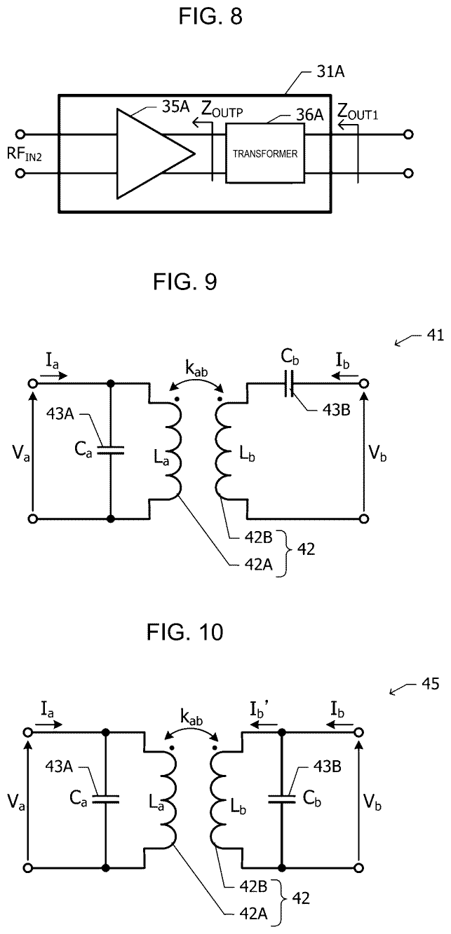

Next, a Doherty amplifier circuit according to a fifth embodiment will be described with reference to FIGS. 8, 9, and 10. In the fifth embodiment, the configuration of the first amplification unit 31A and the second amplification unit 31B included in the Doherty amplifier circuits according to the first embodiment (FIG. 1) and the second embodiment (FIG. 4) and that of the first sub-amplification unit 32A and the second sub-amplification unit 32B included in the Doherty amplifier circuits according to the third embodiment (FIG. 6) and the fourth embodiment (FIG. 7) are more clearly defined.

FIG. 8 is a block diagram of the first amplification unit 31A (FIGS. 1, 4, 6, and 7) included in the Doherty amplifier circuit according to the fifth embodiment. The first amplification unit 31A includes a peaking amplifier 35A and a transformer 36A. The radio frequency signal RF_{IN2} split from the input signal RF_{IN} (FIGS. 1, 4, 6, and 7) is inputted to the peaking amplifier 35A. The transformer 36A transforms the output impedance Z_{OUTP} of the peaking amplifier 35A to Z_{OUT1} and also the phase of the radio frequency signal outputted from the peaking amplifier 35A is shifted.

As with the first amplification unit 31A, the second amplification unit 31B included in the Doherty amplifier circuits according to the first embodiment (FIG. 1) and the second embodiment (FIG. 4) and the first sub-amplification unit 32A and the second sub-amplification unit 32B included in the Doherty amplifier circuits according to the third embodiment (FIG. 6) and the fourth embodiment (FIG. 7) also include a peaking amplifier and a transformer.

The specific configuration of the transformer 36A is described in detail in Japanese Unexamined Patent Application Publication No. 2021-192476. In the following, a specific configuration of the transformer 36A will be briefly described with reference to FIGS. 9 and 10. As the transformer 36A, either a transformer that performs impedance transformation such that the first amplification unit 31A can be considered a current source or a transformer that performs impedance transformation such that the first amplification unit 31A can be considered a voltage source is used.

FIG. 9 is an equivalent circuit diagram of a first transformer 41 that performs impedance transformation such that the first amplification unit 31A (FIG. 8) or the like can be considered a current source. The first transformer 41 includes a transformer unit 42, an input-side capacitor 43A, and an output-side capacitor 43B. The input-side capacitor 43A is connected in parallel with a primary inductor 42A of the transformer unit 42. The output-side capacitor 43B is connected in series with a secondary inductor 42B of the transformer unit 42.

The operating angular frequency of the peaking amplifier 35A is denoted as ω₀, and the inductance of the primary inductor 42A and that of the secondary inductor 42B are denoted as Lₐ and L_{b}, respectively. The capacitance of the input-side capacitor 43A and that of the output-side capacitor 43B are denoted as Cₐ and C_{b}, respectively. The coupling coefficient of the transformer unit 42 is denoted as k_{ab}. An input-side voltage and an input-side current are denoted as Vₐ and Iₐ, respectively, and an output-side voltage and an output-side current are denoted as V_{b} and I_{b}, respectively. If each parameter is chosen so that the following equations are satisfied, the off-diagonal elements of the dependent matrix of the first transformer 41 become zero.

$${ω}_{0}^{2} {L}_{a} {C}_{a} = 1 \qquad ( 1 )$$

$${ω}_{0}^{2} {L}_{b} {C}_{b} = \frac{1}{1 - {k}_{ab}^{2}} \qquad ( 2 )$$

Choosing the parameters to satisfy Equations (1) and (2) yields the following dependent matrix.

$$[ \begin{matrix}{V}_{a} \\ {I}_{a}\end{matrix} ] = [ \begin{matrix}\frac{1}{{k}_{ab}} \sqrt{\frac{{L}_{a}}{{L}_{b}}} & 0 \\ 0 & {k}_{ab} \sqrt{\frac{{L}_{b}}{{L}_{a}}}\end{matrix} ] [ \begin{matrix}{V}_{b} \\ - {I}_{b}\end{matrix} ] \qquad ( 3 )$$

Equation (3) means that the first transformer 41 illustrated in FIG. 9 outputs the voltage and the current multiplied by respective constants. In a configuration using the first transformer 41 illustrated in FIG. 9 as the transformer 36A (FIG. 8), in a case where the peaking amplifier 35A can be considered a current source, the first amplification unit 31A can also be considered a current source.

FIG. 10 is an equivalent circuit diagram of a second transformer 45 that performs impedance transformation such that the first amplification unit 31A (FIG. 8) can be considered a voltage source. In the first transformer 41 illustrated in FIG. 9, the output-side capacitor 43B is connected in series with the secondary inductor 42B; however, in the second transformer 45 illustrated in FIG. 10, the output-side capacitor 43B is connected in parallel with the secondary inductor 42B of the transformer unit 42.

If each parameter is chosen so that the following equations are satisfied, the diagonal elements of the dependent matrix of the second transformer 45 become zero.

$${ω}_{0}^{2} {L}_{a} {C}_{a} = \frac{1}{1 - {k}_{ab}^{2}} \qquad ( 4 )$$

$${ω}_{0}^{2} {L}_{b} {C}_{b} = \frac{1}{1 - {k}_{ab}^{2}} \qquad ( 5 )$$

Choosing the parameters to satisfy Equations (4) and (5) yields the following dependent matrix.

$$[ \begin{matrix}{V}_{a} \\ {I}_{a}\end{matrix} ] = [ \begin{matrix}0 & j \frac{( 1 - {k}_{ab}^{2} ) {ω}_{0} \sqrt{{L}_{a} {L}_{b}}}{{k}_{ab}} \\ j \frac{{k}_{ab}}{( 1 - {k}_{ab}^{2} ) {ω}_{0} \sqrt{{L}_{a} {L}_{b}}} & 0\end{matrix} ] [ \begin{matrix}{V}_{b} \\ - {I}_{b}\end{matrix} ] \qquad ( 6 )$$

Here, j denotes the imaginary unit used when representing radio frequency current and radio frequency voltage as complex numbers.

Equation (6) means that the second transformer 45 illustrated in FIG. 10 interchanges the voltage and the current, and outputs them multiplied by respective constants. In a configuration using the second transformer 45 illustrated in FIG. 10 as the transformer 36A (FIG. 8), in a case where the peaking amplifier 35A can be considered a current source, the first amplification unit 31A can be considered a voltage source. That is, the second transformer 45 has a function of making the output impedance Z_{OUT1} of the first amplification unit 31A (FIG. 8) lower than the output impedance Z_{OUTP} of the peaking amplifier 35A.

As an example, in a case where it is desired to perform impedance transformation such that the first amplification unit 31A can be considered a current source as in the carrier amplifier unit 20 of the first embodiment (FIG. 1) and the carrier amplifier unit 20 of the third embodiment (FIG. 6), it is sufficient that the first transformer 41 (FIG. 9) be used as the transformer 22. In a case where it is desired to perform impedance transformation such that the first amplification unit 31A can be considered a voltage source as in the carrier amplifier unit 20 of the second embodiment (FIG. 4) and the carrier amplifier unit 20 of the fourth embodiment (FIG. 7), it is sufficient that the second transformer 45 (FIG. 10) be used as the transformer 22.

In a case where it is desired to make the output impedance Z_{OUT1} relatively lower as in the first amplification unit 31A of the first embodiment (FIG. 1), it is sufficient that the second transformer 45 (FIG. 10) be used as the transformer. In contrast, in a case where it is desired to make the output impedance Z_{OUT2} relatively higher as in the second amplification unit 31B of the first embodiment (FIG. 1), it is sufficient that the first transformer 41 (FIG. 9) be used as the transformer.

Similarly, as the transformer of the first amplification unit 31A according to the second embodiment (FIG. 4), it is sufficient that the first transformer 41 (FIG. 9) be used. Moreover, it is sufficient that the second transformer 45 (FIG. 10) be used as the transformer of the second amplification unit 31B. As the transformer of the first amplification unit 31A and that of the second sub-amplification unit 32B according to the third embodiment (FIG. 6), it is sufficient that the second transformer 45 (FIG. 10) be used. As the transformer of the first sub-amplification unit 32A, it is sufficient that the first transformer 41 (FIG. 9) be used.

As the transformer of the first amplification unit 31A and that of the second sub-amplification unit 32B according to the fourth embodiment (FIG. 7), it is sufficient that the first transformer 41 (FIG. 9) be used. As the transformer of the first sub-amplification unit 32A, it is sufficient that the second transformer 45 (FIG. 10) be used.

Next, an effect of the fifth embodiment will be described. Transformer miniaturization can be achieved by configuring the first transformer 41 (FIG. 9) and the second transformer 45 (FIG. 10) using the transformer unit 42, the input-side capacitor 43A, and the output-side capacitor 43B. This allows the Doherty amplifier circuit to be miniaturized.

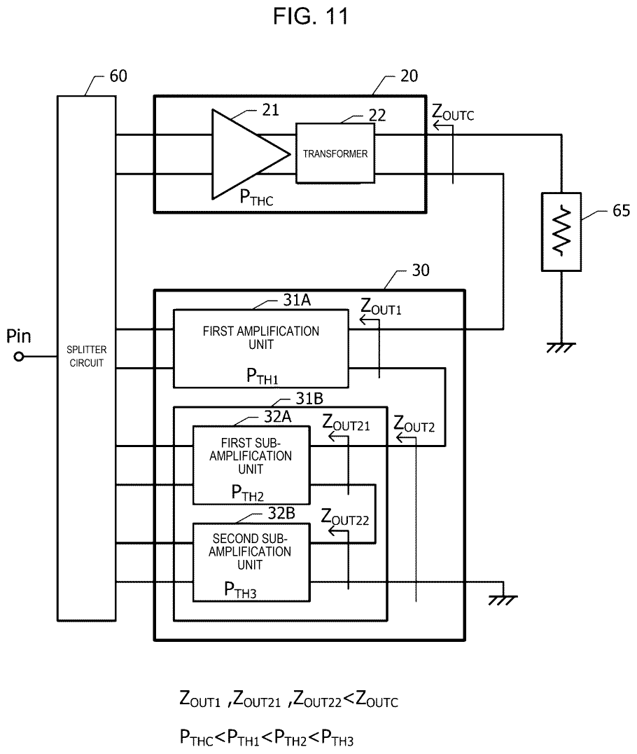

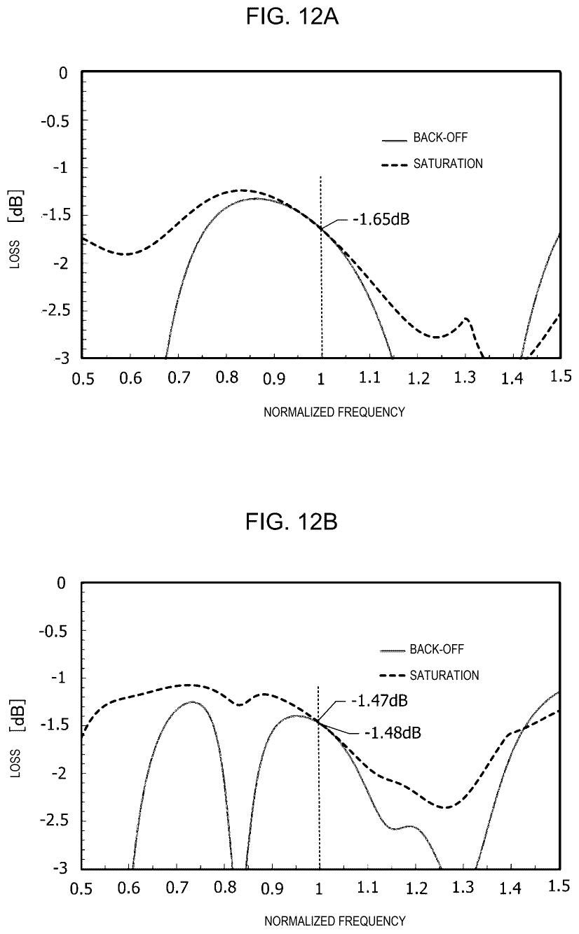

Next, with reference to FIGS. 12A and 12B, an effect of the configuration in which the first transformer 41 (FIG. 9) or the second transformer 45 (FIG. 10) is used as each transformer of the Doherty amplifier circuit according to the third embodiment (FIG. 6) will be described in comparison with a Doherty amplifier circuit according to a comparative example illustrated in FIG. 11.

FIG. 11 is a block diagram of the Doherty amplifier circuit according to the comparative example. As with the Doherty amplifier circuit according to the third embodiment (FIG. 6), the comparative example illustrated in FIG. 11 includes the carrier amplifier unit 20, the first amplification unit 31A, and the second amplification unit 31B, and the second amplification unit 31B includes the first sub-amplification unit 32A and the second sub-amplification unit 32B. In the comparative example illustrated in FIG. 1, the output-side connection configuration is different from that in the third embodiment, and the carrier amplifier unit 20, the first amplification unit 31A, the first sub-amplification unit 32A, and the second sub-amplification unit 32B are connected in series on the output side.

The carrier amplifier unit 20 can be considered a current source. That is, the output impedance Z_{OUTC} of the carrier amplifier unit 20 is higher than any one of the output impedance Z_{OUT1} of the first amplification unit 31A, the output impedance Z_{OUT21} of the first sub-amplification unit 32A, and the output impedance Z_{OUT22} of the second sub-amplification unit 32B.

FIG. 12A is a graph illustrating calculation results of the frequency dependence of the loss of the Doherty amplifier circuit according to the comparative example (FIG. 11), and FIG. 12B is a graph illustrating calculation results of the frequency dependence of the loss of the Doherty amplifier circuit according to the third embodiment (FIG. 6). The horizontal axis represents normalized frequency, and the vertical axis represents the loss in units of dB. In this case, the loss means the loss when the sum of the powers of the radio frequency signals outputted from the output nodes of the carrier amplifier unit 20, the first amplification unit 31A, the first sub-amplification unit 32A, and the second sub-amplification unit 32B is the input and the power consumed by the load 65 is the output.

In the calculations of the losses illustrated in FIGS. 12A and 12B, the first transformer 41 (FIG. 9) is used as the transformer 22 of the carrier amplifier unit 20 and the transformer of the first sub-amplification unit 32A according to the third embodiment (FIG. 6), and the second transformer 45 (FIG. 10) is used as the transformer of the first amplification unit 31A and the transformer of the second sub-amplification unit 32B. As the transformer 22 of the carrier amplifier unit 20 according to the comparative example (FIG. 11), the first transformer 41 (FIG. 9) is used. The second transformer 45 (FIG. 10) is used as the transformer of the first amplification unit 31A, that of the first sub-amplification unit 32A, and that of the second sub-amplification unit 32B. Let the impedance of the load 65 (FIGS. 3 and 11) be 16Ω, the coupling coefficient k_{ab} of the transformer unit 42 (FIGS. 9 and 10) be 0.7, and the Q factor of the transformer unit 42 (FIGS. 9 and 10) be 20.

The solid lines illustrated in FIGS. 12A and 12B represent the losses in the back-off region, for example, when operating under conditions where the input power P_{IN} is equal to the operation start level P_{TH1} of the peaking amplifier unit 30, and the broken lines represent the losses when all of the carrier amplifier unit 20, the first amplification unit 31A, the first sub-amplification unit 32A, and the second sub-amplification unit 32B operate in the saturation region. When the normalized frequency is 1, the loss is 1.65 dB in both the back-off region and the saturation region in the comparative example (FIG. 11), as illustrated in FIG. 12A. In contrast, the loss in the back-off region is 1.48 dB and the loss in the saturation region is 1.47 dB in the third embodiment (FIG. 6), as illustrated in FIG. 12B.

It is confirmed that the Doherty amplifier circuit according to the third embodiment (FIG. 6) has lower losses than the Doherty amplifier circuit according to the comparative example illustrated in FIG. 11. The reasons for the lower losses in the Doherty amplifier circuit according to the third embodiment (FIG. 6) are as follows.

In the comparative example illustrated in FIG. 11, the output current from the carrier amplifier unit 20 equally flows through all of the first amplification unit 31A, the first sub-amplification unit 32A, and the second sub-amplification unit 32B in the back-off region, resulting in losses in each amplification unit. In the saturation region where the first amplification unit 31A is operating, the output current from the first amplification unit 31A equally flows through both the first sub-amplification unit 32A and the second sub-amplification unit 32B, resulting in losses in the two sub-amplification units.

In contrast, in the back-off region in the third embodiment (FIG. 6), the output current from the carrier amplifier unit 20 mainly flows through the first amplification unit 31A having the output impedance Z_{OUT1}, which is relatively low, and a small amount of current flows through the second amplification unit 31B having the output impedance Z_{OUT2}, which is relatively high. The loss is reduced because little loss occurs in the second amplification unit 31B. In the saturation region where the first amplification unit 31A is operating, the output voltage from the first amplification unit 31A mainly applies to the first sub-amplification unit 32A having the output impedance Z_{OUT21}, which is relatively high, and a low voltage is applied to the second sub-amplification unit 32B having the output impedance Z_{OUT22}, which is relatively low. Thus, the loss is reduced.

Next, a modification of the fifth embodiment will be described.

In the fifth embodiment, the first transformer 41 (FIG. 9) and the second transformer 45 (FIG. 10) are realized using the transformer unit 42, the input-side capacitor 43A, and the output-side capacitor 43B, the first transformer 41 performing impedance transformation such that the amplification unit can be considered a current source, the second transformer 45 performing impedance transformation such that the amplification unit can be considered a voltage source. However, other configurations may be used.

For example, the second transformer 45 that performs impedance transformation such that the amplification unit can be considered a voltage source can be realized using a quarter-wavelength transmission line. Alternatively, a circuit with functions equivalent to the quarter-wavelength transmission line can be realized using a lumped element. The first transformer 41 that performs impedance transformation such that the amplification unit can be considered a current source can be realized using a half-wavelength transmission line. Alternatively, the first transformer 41 can be realized by combining the second transformer 45 with a quarter-wavelength transmission line.

As in the modification of the fifth embodiment, a low-loss transformer can be realized by configuring the transformers using transmission lines.

### Sixth Embodiment

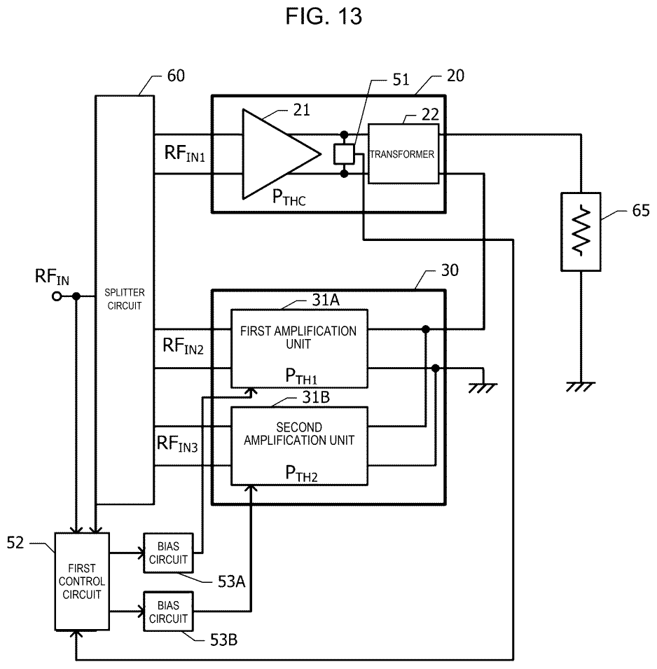

Next, a Doherty amplifier circuit according to a sixth embodiment will be described with reference to FIG. 13. In the following, description of the configuration common to that of the Doherty amplifier circuit according to the first embodiment described with reference to FIGS. 1, 2A, and 2B will be omitted.

FIG. 13 is a block diagram of the Doherty amplifier circuit according to the sixth embodiment. Bias circuits 53A and 53B supply bias to the first amplification unit 31A and the second amplification unit 31B, respectively. Note that the illustration of the bias circuits is omitted in FIG. 1 and the like.

The Doherty amplifier circuit according to the sixth embodiment includes a drive level detection circuit 51 connected between the output nodes of the carrier amplifier 21. The drive level detection circuit 51 detects the drive level (operation level) of the carrier amplifier 21, based on the radio frequency signal outputted from the carrier amplifier 21. The detection result is inputted to a first control circuit 52. The input signal RF_{IN} is also inputted to the first control circuit 52. Note that the configuration may also be used in which the radio frequency signal RF_{IN1} inputted to the carrier amplifier unit 20 is inputted to the first control circuit 52.

An example of the detailed configuration of the first control circuit 52 is described in, for example, Japanese Unexamined Patent Application Publication No. 2024-146719. In the following, the function of the first control circuit 52 will be described. The first control circuit 52 controls the bias circuits 53A and 53B, based on the input signal RF_{IN} and the drive level of the carrier amplifier 21. For example, the first control circuit 52 controls the start and stop of bias supply to the first amplification unit 31A and the second amplification unit 31B from the bias circuits 53A and 53B, respectively. That is, the first control circuit 52 varies the operation start level P_{TH1} of the first amplification unit 31A and the operation start level P_{TH2} of the second amplification unit 31B in the peaking amplifier unit 30, based on the drive level of the carrier amplifier 21.

Next, an effect of the sixth embodiment will be described.

In the sixth embodiment, since the operation start levels P_{TH1} and P_{TH2} of the peaking amplifier unit 30 are varied in response to the drive level of the carrier amplifier 21, even when changes occur in environmental temperature or the like, the operation start levels P_{TH1} and P_{TH2} of the peaking amplifier unit 30 can be appropriately adjusted.

Next, a Doherty amplifier circuit according to a modification of the sixth embodiment will be described.

In the sixth embodiment, the first control circuit 52 controls the bias circuits 53A and 53B to vary the operation start levels P_{TH1} and P_{TH2} of the first amplification unit 31A and the second amplification unit 31B. As an alternative, the first control circuit 52 may directly control the first amplification unit 31A and the second amplification unit 31B to vary the operation start levels P_{TH1} and P_{TH2}.

### Seventh Embodiment

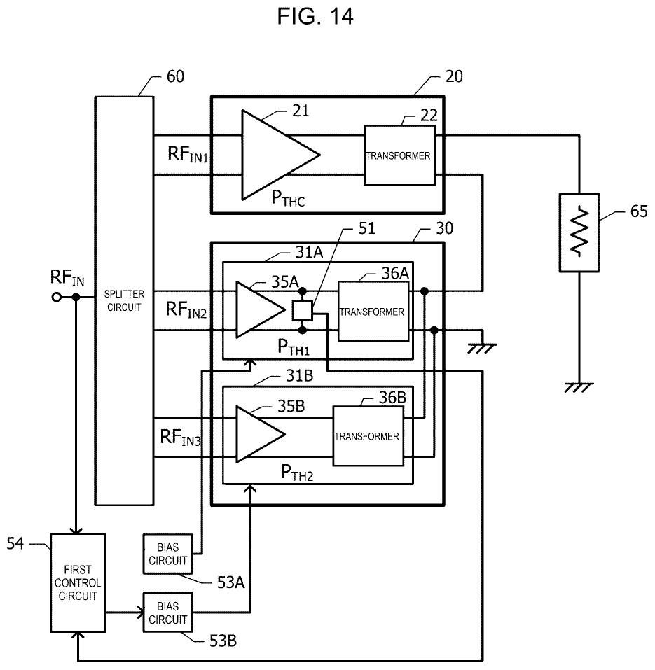

Next, a Doherty amplifier circuit according to a seventh embodiment will be described with reference to FIG. 14. In the following, description of the configuration common to that of the Doherty amplifier circuit according to the sixth embodiment described with reference to FIG. 13 will be omitted.

FIG. 14 is a block diagram of the Doherty amplifier circuit according to the seventh embodiment. The first amplification unit 31A includes the peaking amplifier 35A and the transformer 36A, as illustrated in FIG. 8. Similarly, the second amplification unit 31B includes a peaking amplifier 35B and a transformer 36B.

In the sixth embodiment (FIG. 13), the drive level detection circuit 51 is connected between the output nodes of the carrier amplifier 21. In contrast, in the seventh embodiment, the drive level detection circuit 51 is connected between the output nodes of the peaking amplifier 35A of the first amplification unit 31A. The drive level detection circuit 51 detects the drive level of the peaking amplifier 35A, based on the radio frequency signal outputted from the peaking amplifier 35A. The detection result is inputted to a second control circuit 54. The input signal RF_{IN} is also inputted to the second control circuit 54. Note that the configuration may also be used in which the radio frequency signal R_{FIN2} inputted to the first amplification unit 31A is inputted to the second control circuit 54.

The second control circuit 54 controls the bias circuit 53B, based on the input signal RF_{IN} and the drive level of the peaking amplifier 35A. For example, the second control circuit 54 controls the start and stop of bias supply to the second amplification unit 31B by controlling the bias circuit 53B. That is, the second control circuit 54 varies the operation start level P_{TH2} of the second amplification unit 31B, based on the drive level of the peaking amplifier 35A. Note that the bias circuit 53A, which supplies bias to the first amplification unit 31A, is not controlled by the second control circuit 54. Next, an effect of the sixth embodiment will be described.

In the sixth embodiment, since the operation start level P_{TH2} of the second amplification unit 31B is varied in response to the drive level of the peaking amplifier 35A, even when changes occur in environmental temperature or the like, the operation start level P_{TH2} of the second amplification unit 31B can be appropriately adjusted.

Next, a Doherty amplifier circuit according to a modification of the sixth embodiment will be described.

In the sixth embodiment, the peaking amplifier unit 30 includes the two peaking amplifiers 35A and 35B; however, for example, similar bias control can be performed even in a case where the peaking amplifier unit 30 includes three peaking amplifiers, as illustrated in FIGS. 6, 7, and the like. For example, the configuration may be used in which the operation start level of the peaking amplifier having a relatively high operation start level is varied based on the drive level of the peaking amplifier having a relatively low operation start level.

In the sixth embodiment, the second control circuit 54 controls the bias circuit 53B to vary the operation start level P_{TH2} of the second amplification unit 31B. As an alternative, the second control circuit 54 may directly control the second amplification unit 31B to vary the operation start level P_{TH2}.

Each of the above-mentioned embodiments is illustrative, and partial substitutions or combinations of the configurations of the different embodiments are possible. Similar operational effects achieved by similar configurations in the multiple embodiments will not be described repeatedly for each embodiment. Furthermore, the present disclosure is not limited to the above-mentioned embodiments. For example, it will be apparent to those skilled in the art that, for example, various modifications, improvements, combinations, and the like may be made.

What is claimed is:

1. A Doherty amplifier circuit comprising:
a carrier amplifier unit comprising a carrier amplifier to which a radio frequency signal split from an input signal is input and that is configured to amplify and to output the input radio frequency signal, and a transformer that is configured to transform an output impedance of the carrier amplifier; and
a peaking amplifier unit comprising a first amplifier and a second amplifier, to which a radio frequency signal split from the input signal is input, and that is configured to amplify and to output the input radio frequency signal,
wherein in a case where a power level of the input signal at a start of an amplification operation is an operation start level, the peaking amplifier unit has a higher operation start level than the carrier amplifier unit,
wherein the carrier amplifier unit and the peaking amplifier unit are connected on an output side in a first connection configuration,
wherein the first amplifier and the second amplifier are connected on the output side in a second connection configuration, which is different from the first connection configuration,
wherein each of the first amplifier and the second amplifier is configured to amplify and to output the radio frequency signals split from the input signal, and
wherein the first amplifier and the second amplifier have different output impedances, and the first amplifier has a lower operation start level than the second amplifier.

2. The Doherty amplifier circuit according to claim 1,
wherein the first connection configuration is a series connection,
wherein the first amplifier has a lower output impedance than the second amplifier,
wherein and the first amplifier has a lower output impedance than the carrier amplifier unit.

3. The Doherty amplifier circuit according to claim 2,
wherein the second amplifier comprises a first sub-amplifier and a second sub-amplifier connected in series on the output side,
wherein the first sub-amplifier has a higher output impedance than the second sub-amplifier, and
wherein the first sub-amplifier has a lower operation start level than the second sub-amplifier.

4. The Doherty amplifier circuit according to claim 3,
wherein each of the first amplifier, the first sub-amplifier, and the second sub-amplifier comprises a peaking amplifier that is configured to amplify and to output an input radio frequency signal, and a transformer that is configured to transform an output impedance of the peaking amplifier,
wherein the transformer of the first amplifier and the transformer of the carrier amplifier unit are configured such that the first amplifier has a lower output impedance than the carrier amplifier unit, and
wherein the transformer of the first sub-amplifier and the transformer of the second sub-amplifier are configured such that the second sub-amplifier has a lower output impedance than the first sub-amplifier.

5. The Doherty amplifier circuit according to claim 1,
wherein the first connection configuration is a parallel connection, and
wherein the first amplifier has a higher output impedance than the second amplifier, and the first amplifier has a higher output impedance than the carrier amplifier unit.

6. The Doherty amplifier circuit according to claim 5,
wherein the second amplifier comprises a first sub-amplifier and a second sub-amplifier connected in parallel on the output side,
wherein the first sub-amplifier has a lower output impedance than the second sub-amplifier, and
wherein the first sub-amplifier has a lower operation start level than the second sub-amplifier.

7. The Doherty amplifier circuit according to claim 6,
wherein each of the first amplifier, the first sub-amplifier, and the second sub-amplifier comprises a peaking amplifier that is configured to amplify and to output an input radio frequency signal, and a transformer that is configured to transform an output impedance of the peaking amplifier,
wherein the transformer of the carrier amplifier unit and the transformer of the first amplifier are configured such that the carrier amplifier unit has a lower output impedance than the first amplifier, and
wherein the transformer of the first sub-amplifier and the transformer of the second sub-amplifier are configured such that the first sub-amplifier has a lower output impedance than the second sub-amplifier.

8. The Doherty amplifier circuit according claim 1, further comprising:
a first control circuit that is configured to vary the operation start level of the peaking amplifier unit based on a drive level of the carrier amplifier.

9. The Doherty amplifier circuit according to claim 1, further comprising:
a second control circuit that is configured to vary the operation start level of the second amplifier based on a drive level of the first amplifier.
